(19) United States
(12) Patent Application Publication
(10) Pub. No.: US 2009/0164685 A1
(43) Pub. Date: Jun. 25, 2009

(54) EXPANSION DEVICE FOR HARD DISK DRIVE

(75) Inventors: XIAO-ZHU CHEN, Shenzhen (CN); ZHEN-XING YE, Shenzhen (CN); MING-KE CHEN, Shenzhen (CN); KE SUN, Shenzhen (CN); HSIU-CHANG LAI, Tu-Cheng (TW)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/100,427

(22) Filed: Apr. 10, 2008

(30) Foreign Application Priority Data
Dec. 24, 2007 (CN) 200710203366.9

(51) Int. Cl. H05K 7/10

(52) U.S. Cl. 710/301

(57) ABSTRACT

An expansion device includes a peripheral component interconnect (PCI) card, a hard disk connector, a hard disk drive (HDD), and a signal converter. The PCI card includes PCI pins for connecting to a PCI slot of a motherboard of a computer. The connector is arranged on the PCI card. The HDD is attached to the PCI card and connected to the connector. The signal converter is connected between the hard disk connector and the PCI pins. The signal converter receives a PCI signal from the PCI slot through the PCI pins, and converts the PCI signal to a signal suitable for and provided to a HDD through the connector. When the HDD completes reading and writing, the signal converter receives a feedback signal from the HDD through the connector, and converts the feedback signal to a PCI signal for being provided to the motherboard through the PCI pins.

### BACKGROUND

1. Field of the Invention

The present invention relates to expansion devices, and particularly to an expansion device for hard disk drive (HDD).

2. Description of Related Art

With advances in computer technology, computers have become needful tools in people's daily life and in business. Thus, a great deal of data storage space for storing information is needed, which is loaded in HDDs. Generally, in a personal computer, the HDDs are accommodated in a bracket that is mounted in the computer, but a capacity of the bracket is limited, thus the bracket can only receive a limited quantity of HDDs. On the other hand, a plurality of expansion slots for mounting expansion cards, such as peripheral component interconnect (PCI) cards, accelerated graphics ports (AGP) cards, and industrial standard architecture (ISA) interconnects cards, is set on a motherboard in the computer, but it is not unusual for only some or none of the expansion slots used, which leads to a waste of the expansion slots and space above the slots.

What is needed, therefore, is an expansion device for HDDs which advantageously utilizes the unused expansion slots and space above the expansion slots in the computer for receiving the HDDs.

### SUMMARY

An exemplary expansion device includes a peripheral component interconnect (PCI) card, a hard disk connector, a hard disk drive (HDD), and a signal converter. The PCI card includes PCI pins for connecting to a PCI slot of a motherboard of a computer. The connector is arranged on the PCI card. The HDD is attached to the PCI card and connected to the connector. The signal converter is connected between the connector and the PCI pins. The signal converter receives a PCI signal from the PCI slot of the motherboard through the PCI pins, and converts the PCI signal to a signal suitable for and provided to the HDD through the connector for controlling reading and writing of the HDD. When the HDD completes reading and writing, the signal converter receives a feedback signal from the HDD through the connector, and converts the feedback signal to a PCI signal for being provided to the motherboard through the PCI pins, such that the HDD communicates with the motherboard.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is a schematic diagram of an expansion device for HDDs in accordance with an exemplary embodiment of the present invention; and

FIG. 2 is a circuit diagram of the FIG. 1.

### DETAILED DESCRIPTION

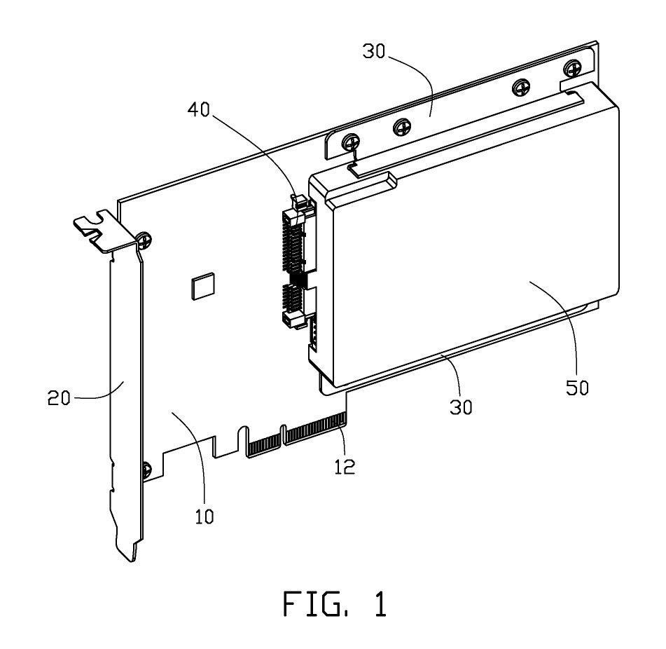

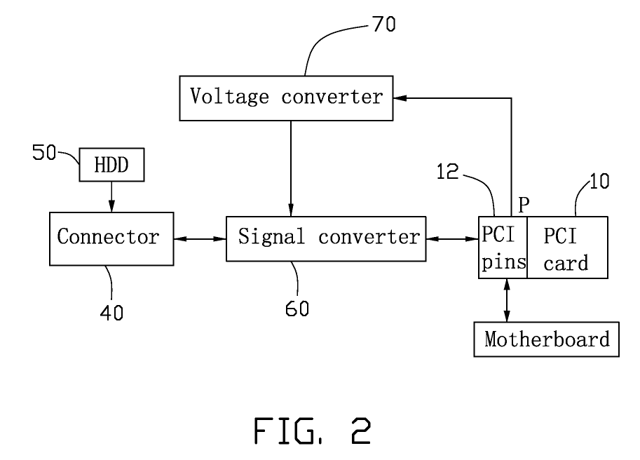

Referring to FIGS. 1 and 2, an expansion device for HDDs in accordance with an exemplary embodiment of the present invention includes a peripheral component interconnect (PCI) card 10, a bracket 20, a fixture 30, a hard disk connector 40, an HDD 50, a signal converter 60, and a voltage converter 70. The PCI card 10 is rectangular-shaped. PCI pins 12 are set on a long edge of the PCI card 10 for connecting to a PCI slot of a motherboard of a computer. The bracket 20 is fixed to one of two opposite short edges of the PCI card 10 by two screws for attaching the PCI card 10 to a rear panel of the computer. The fixture 30 includes four holes. The HDD 50 can be fixed on the PCI card 10 through four screws mounted in the four holes of the fixture 30 respectively. The connector 40 is arranged on the PCI card 10 for connecting the HDD 50. The HDD 50 is rectangular-shaped. The HDD 50 is parallely attached to one side of the PCI card 10 near the other one of the two opposite short edges, and connected to the connector 40. The signal converter 60 is arranged on the PCI card 10 for converting PCI signals from the PCI slot of the motherboard to signals suitable for the HDD 50. The voltage converter 70 is arranged on the PCI card 10 for converting a 3.3V voltage from the PCI slot of the motherboard to a 1.8V voltage of the signal converter 60.

Referring to FIG. 2, the connector 40 is connected to the PCI pins 1 2 through the signal converter 60. A power pin P of the PCI pins 1 2 is connected to the signal converter 60 through the voltage converter 70. The signal converter 60 can communicate with the HDD 50 through the connector 40, and communicate with the motherboard through the PCI pins 1 2 engaging in the PCI slot of the motherboard. The PCI slot of the motherboard provides a 3.3V working voltage to the voltage converter 70. The voltage converter 70 converts the 3.3V voltage to a 1.8V voltage of the signal converter 60. The voltage converter 70 can be deleted to save on cost.

In this embodiment, the HDD 50 is a 2.5 inch serial ATA (SATA) HDD. The signal converter 60 is a SiI3531 chip. The connector 40 is a SATA HDD connector. The signal converter 60 and the HDD 50 can be selected according to need.

In use, the PCI card 10 is mounted in the PCI slot of the motherboard of the computer through the PCI pins 12. When the computer is powered on, the operation system of the computer controls the south-bridge chip to set related parameters of peripheral equipment of the computer, and then the signal converter 60 is used by the operation system of the computer. The voltage converter 70 receives the 3.3V voltage from the PCI slot of the computer, and converts the 3.3V voltage to the 1.8V voltage of the signal converter 60. When the operation system of the computer accesses the HDD 50, the operation system controls the south-bridge chip of the computer to send a PCI instruction to the signal converter 60. The signal converter 60 converts the PCI instruction to a SATA signal and provides it to the HDD 50 through the connector 40 for controlling reading and writing of the HDD 50. When the HDD 50 completes reading and writing, the signal converter 60 receives a feedback signal from the HDD 50 through the connector 40, and converts the feedback signal to a PCI signal and provides it to the south-bridge chip of the computer through the PCI slot. Therefore, the computer can provide the reading and writing data of the HDD 50 to users.

The expansion device for HDDs advantageously utilizes the unused expansion slots and space above the expansion slots in the computer for receiving the HDDs, and extends the storage capacity of the computer system.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An expansion device comprising:
a peripheral component interconnect (PCI) card comprising PCI pins for connecting to a PCI slot of a motherboard of a computer;
a hard disk connector arranged on the PCI card;
a hard disk drive (HDD) attached to the PCI card and connected to the connector; and
a signal converter connected between the connector and the PCI pins, the signal converter receiving a PCI signal from the PCI slot of the motherboard through the PCI pins, and converting the PCI signal to a signal suitable for and provided to the HDD through the connector for controlling reading and writing of the HDD, when the HDD completes reading and writing, the signal converter receives a feedback signal from the HDD through the connector, and converts the feedback signal to a PCI signal for being provided to the motherboard through the PCI pins, such that the HDD communicates with the motherboard.

2. The expansion device as claimed in claim 1, further comprising a voltage converter, wherein a power pin of the PCI pins is connected to the signal converter via the voltage converter.

3. The expansion device as claimed in claim 2, wherein the voltage converter converts a 3.3V voltage from the PCI slot of the motherboard to a 1.8V voltage of the signal converter.

4. The expansion device as claimed in claim 1, further comprising a fixture for fixing the HDD to a side of the PCI card.

5. The expansion device as claimed in claim 4, wherein the fixture comprises a pair of L-shaped plates, each of the plates comprises a first part defining holes therein for screws extending therethrough and engaging in the PCI card, and a second part engaging with a sidewall of the HDD.

6. The expansion device as claimed in claim 1, wherein the PCI card is rectangular-shaped, the PCI pins is set on a long edge of the PCI card.

7. The expansion device as claimed in claim 6, wherein a bracket is fixed to one of two opposite short edges of the PCI card by screws for attaching the PCI card to a rear panel of the computer.

8. The expansion device as claimed in claim 7, wherein the HDD is rectangular-shaped, the HDD is parallely attached to one side of the PCI card near the other one of the two opposite short edges, and connected to the connector.

9. The expansion device as claimed in claim 1, wherein the connector is a SATA HDD connector, and the HDD is a SATA HDD.

10. The expansion device as claimed in claim 1, wherein the signal converter converts PCI signals to SATA signals, and converts SATA signals to PCI signals.
